(19) United States
(12) Patent Application Publication
(10) Pub. No.: US 2026/0068242 A1
(43) Pub. Date: Mar. 5, 2026

(54) WIDE-BANDGAP SUPER JUNCTION STRUCTURES FOR POWER DEVICES

(71) Applicant: Applied Materials, Inc., Santa Clara, CA (US)

(72) Inventor: Amirhasan NOURBAKHSH, Albany, NY (US)

(73) Assignee: Applied Materials, Inc., Santa Clara, CA (US)

(21) Appl. No.: 18/820,088

(22) Filed: Aug. 29, 2024

(51) Int. Cl. H01L 29/06; H01L 21/223; H01L 21/225; H01L 21/302; H01L 29/10; H01L 29/16; H01L 29/20; H01L 29/66; H01L 29/78

(52) U.S. Cl. CPC H10D 62/111; H10D 30/0291; H10D 30/66; H10D 30/751; H10D 62/8325; H10D 62/8503

(57) ABSTRACT

A super junction device may be formed by decreasing the width of the P-type region and increasing the doping concentration, allowing for an increased height of the device. However, instead of etching a trench to fill with the P-type material, a trench may be etched for both the P-type and adjacent N-type regions. This allows the height of the device to be increased while maintaining a feasible aspect ratio for the trench. The P-type material may be formed on the sidewall on the trench to be relatively thin. The trench may then be filled with N-type material such that the P-type region fills the space between the N-type regions without any voids or seams, while having a width that would be unattainable using traditional etch-and-fill methods for the P-type region alone. Wide bandgap materials may also be used to increase the voltage rating.

### TECHNICAL FIELD

The present technology relates to semiconductor systems, processes, and equipment. More specifically, the present technology relates to processes and systems to improve scaling for high-aspect-ratio power devices.

### BACKGROUND

Integrated circuits are made possible by processes which produce intricately patterned material layers on substrate surfaces. Producing patterned material on a substrate requires controlled methods for forming and removing material. As device sizes continue to reduce, features within the integrated circuits may get smaller and aspect ratios of structures may grow, and maintaining dimensions of these structures during processing operations may be challenged. Some processing may result in recessed features in the materials that may have uneven, or tapered, sidewalls due to increased exposure during processing. Developing materials with straight sidewalls may become more difficult. Further, backfilling recessed features with material without any seams and/or voids may also become more difficult.

Thus, there is a need for improved systems and methods that can be used to produce high quality devices and structures. These and other needs are addressed by the present technology.

### SUMMARY

In some embodiments, a super junction device may include a first N-type wide bandgap region extending up from a substrate, where the substrate may form a first contact region for the device. The device may also include a second N-type wide bandgap region extending up from the substrate to a second contact region of the device. The device may additionally include a P-type wide bandgap region disposed between the first N-type wide bandgap region and the second N-type wide bandgap region, where a width of the P-type wide bandgap region may be less than or about 10% of a combined width of the P-type wide bandgap region and the first N-type wide bandgap region.

In some embodiments, a super junction device may include a wide bandgap substrate forming a drain region for the device, a gate region, a source region, an N-type wide bandgap region extending from the wide bandgap substrate up to the gate region; and a P-type wide bandgap region extending up to the source region. The device may have a pitch between centers of N-type wide bandgap regions that is equal to a width of a trench etched to form the P-type wide bandgap region and an adjacent N-type wide bandgap region.

In some embodiments, a method of forming a super junction device may include forming a first N-type wide bandgap material on a wide bandgap substrate. The method may also include etching a trench in the first N-type wide bandgap material. The trench may form at least a first N-type wide bandgap region from the first N-type wide bandgap material. The method may additionally include forming a P-type wide bandgap region along a sidewall of the trench on or in the first N-type wide bandgap region. The method may further include filling the trench with a second N-type wide bandgap material to form a second N-type wide bandgap region such that the P-type wide bandgap region is between the first N-type wide bandgap region and the second N-type wide bandgap region.

In any embodiments, any and all of the following features may be implemented in any combination and without limitation. The first N-type wide bandgap region may include a wide bandgap material with a bandgap greater than 2.0 eV. The width of the P-type wide bandgap region may be less than or about 200 nm. The first contact region may include a drain of a super junction transistor, and the second contact region may include a gate of the super junction transistor. The super junction transistor may have a breakdown voltage of greater than or about 13,000 V. The combined width of the P-type wide bandgap region and the second N-type wide bandgap region may be less than or about 4 μm. A doping concentration of the P-type wide bandgap region may be higher than a doping concentration of the second N-type wide bandgap region. The N-type wide bandgap region may include SiC, GaN, or AlGaN. An aspect ratio of an area occupied by the N-type wide bandgap region and the P-type wide bandgap region may be less than or about 20. A width of an area occupied by the N-type wide bandgap region and the P-type wide bandgap region may be less than or about 4 μm. The trench may be etched above a top surface of the wide bandgap substrate such that the top surface of the wide bandgap substrate is not exposed at a bottom of the trench and the P-type wide bandgap region does not contact the wide bandgap substrate. Forming the P-type wide bandgap region may include epitaxially growing a P-type liner along the sidewall of the trench. Forming the P-type wide bandgap region may include performing a plasma doping (PLAD) operation on the sidewall of the trench where the PLAD operation may dope the sidewall with a P-type dopant, and annealing the sidewall sufficiently to cause the P-type dopant to diffuse into the first N-type wide bandgap region to form the P-type wide bandgap region in the first N-type region. Forming the P-type wide bandgap region may include forming a P-doped layer on a sidewall of the trench including the first N-type wide bandgap region where the P-doped layer includes a P-type dopant, and annealing the P-doped layer sufficiently to cause the P-type dopant to diffuse into the first N-type wide bandgap region to form the P-type wide bandgap region in the first N-type region. The P-doped layer may include boron-doped silicon oxide, boron-doped silicon nitride, or borophosphosilicate (BPSG) glass. A directional etch may be performed to remove any P-type wide bandgap material from a bottom of the trench while leaving the P-type wide bandgap region along the sidewall of the trench. A doping concentration of the N-type region may be between about 1e14 dopants/cm3 and about 1e16 dopants/cm3. A doping concentration of the P-type region may be greater than about 8 times the doping concentration of the N-type region.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of a processing system of deposition, etching, baking, and curing chambers that may be included or configured according to some embodiments of the present technology.

FIG. 2 illustrates a super junction device, according to some embodiments.

FIG. 3 illustrates a flowchart of a method of forming a super junction device with a high breakdown voltage, according to some embodiments.

FIGS. 4A-4G illustrate incremental structures for forming the super junction device with a high breakdown voltage, according to some embodiments.

FIGS. 5A-5B illustrates forming a P-doped layer on a sidewall of the trench, according to some embodiments.

FIG. 6 illustrates how the P-type wide bandgap region may be formed in the N-type wide bandgap material using a plasma doping technique, according to some embodiments.

### DETAILED DESCRIPTION

A super junction device with an increased voltage rating may be formed by decreasing the width of the P-type region and increasing the doping concentration, while also increasing the height of the overall device. However, instead of etching a trench in the N-type material to fill with the P-type material, a trench may be etched for both the P-type region and an adjacent N-type region. This allows the height of the overall device to be increased while maintaining a feasible aspect ratio for the trench. The P-type material may then be formed along the sidewall of the N-type may say using a number of different techniques. For example, the P-type material may be formed as a sidewall liner on the trench that is relatively thin compared to the remaining width of the trench. Alternatively, a P-type dopant may be diffused into the sidewalls to form a P-type material, or the sidewalls may be doped with the P-type dopant using a plasma doping process. The trench may then be filled with N-type material such that the P-type region fills the space between the N-type regions without any voids or seams, while having a width that would be unattainable using traditional etch-and-fill methods for the P-type region alone. Additionally, replacing traditional silicon with wide bandgap materials may dramatically increase the breakdown voltage of a super junction device.

As device sizes continue to shrink, many material layers may be reduced in thickness and size to scale devices. Features inside semiconductor structures may be reduced in size, and aspect ratios of the features may increase. As the aspect ratios of the features increase, patterning operations may struggle to uniformly etch features without tapering the sidewalls of the feature, or compromising feature dimensions or integrity, due to increased exposure nearer a surface of the substrate material being processed. Further, refilling a feature with higher aspect ratios may be increasingly difficult due to pinch off at the top of the feature that prevents the feature from being filled without seams and/or voids.

In forming power device structures, conventional technologies have been limited in device scaling for increased aspect ratio features based on the natural effects of prolonged etching and deposition operations. For example, in super junction structures, P-type silicon pillars are formed by filling trenches etched into N-type silicon with P-type material. In these structures, the on-resistance is controlled by the pitch or width of the different materials. The resistance may be improved by reducing the width of the P-type silicon pillars. Scaling the P-type silicon pillars is limited by etching and seam and/or void free trench filling capabilities. For example, increasing the aspect ratio with conventional etching may cause pitch degradation and tapered features due to the prolonged exposure of upper regions of the feature being formed.

Additionally, the fill operation of high-aspect ratio features may lead to pinch off before deeper regions of the feature are filled. Consequently, conventional technologies have been limited to lower aspect ratios, or shorter structures to limit performance effects or device failure. Accordingly, many conventional technologies have been limited in the ability to prevent structural flaws in the final devices or improve on historical designs.

Additionally, traditional super junction devices have used silicon as the primary fill material for both the N-type and P-type regions. For example, the substrate would be a highly doped N+ silicon substrate on which an N-type silicon material is deposited. Trenches were then etched into the N-type silicon material and filled with P-type silicon material. However, silicon has a relatively low critical electric field compared to other materials. Specifically, it has been discovered that the higher critical electric field of wide bandgap materials can be used to form devices with exceptionally high breakdown voltages with similar sizes. For example, a device formed primarily using silicon carbide (SiC) instead of traditional silicon can generate a similar breakdown voltage with approximately 1/10 the height. Therefore, a traditional 600 V silicon device approximately 40 μm high may equate to a 6000 V silicon carbide device with the same height.

The present technology overcomes these issues by redefining the way in which the pillars are formed in the base material, and by using wide bandgap materials, such as silicon carbide, gallium nitride, aluminum gallium nitride, and other similar materials. By forming thin P-type layers on the sidewalls of the N-type mesas within a wider overall feature prior to backfill, the P-type pillars of material can be maintained at much smaller widths compared to conventional technologies. More specifically, the width of the P-type pillars of material may be defined by the width of the epitaxial, diffuse, or doped liner rather than the width of the recessed features. In fact, the recessed features can be made wider than conventional technologies as two P-type pillars may be deposited on sidewalls of each recessed feature. After forming materials wide bandgap P-type regions on the sidewalls, the recessed features may be backfilled with additional base N-type wide bandgap material. By changing the formation process itself, the present technology may afford much greater aspect ratio features, and also may prevent or reduce defects in final devices based on more uniform fill and coverage.

Although the remaining disclosure will routinely identify specific etching and deposition processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

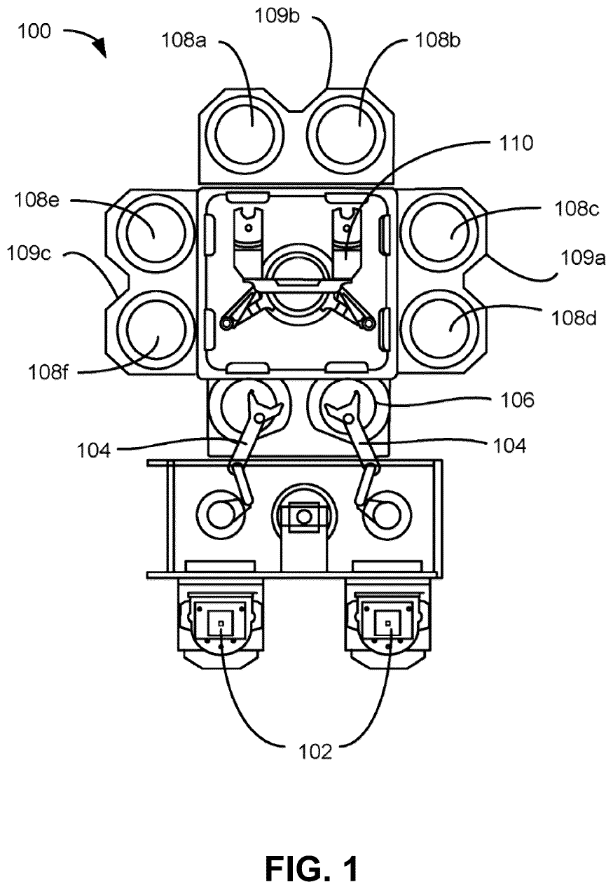

FIG. 1 shows a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

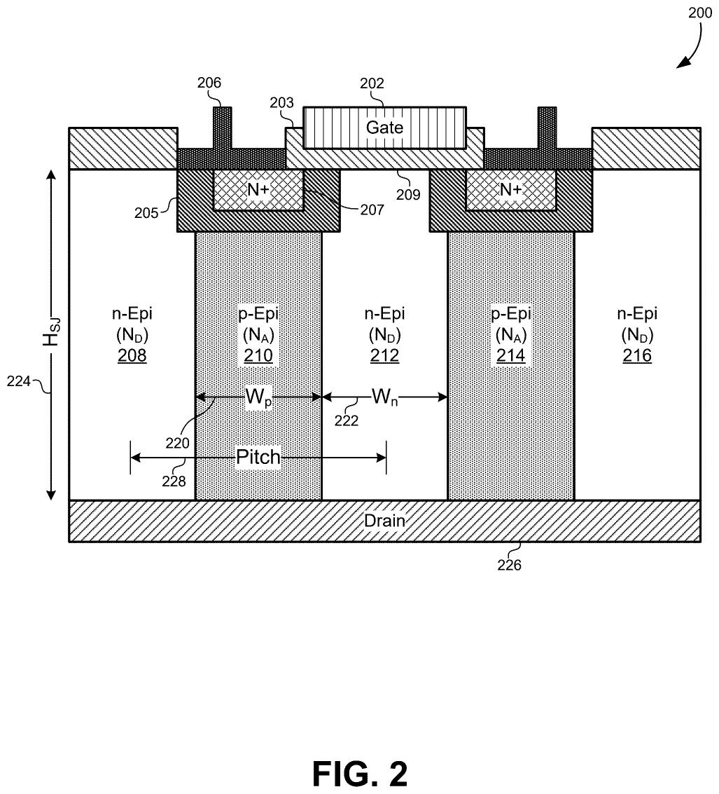

System 100, or more specifically chambers incorporated into system 100 or other processing systems, may be used to produce structures according to some embodiments of the present technology. FIG. 2 illustrates a traditional super junction device 200, according to some embodiments. The device 200 in FIG. 2 is represented by example as a super junction transistor, such as a super junction MOSFET. However, the principles described herein may be used to form any super junction device, and the description is not limited to a super junction transistor.

The device 200 may include a number of different electrical contacts. The device 200 may include a source contact 206 that is electrically coupled to an N+ source region 207 that is formed within a P-well 205. Collectively, the source contact 206, the N+ source region 207, and the P-well 205 may be referred to as a “source region” of the device 200. The device may be formed on a silicon substrate 226. The silicon substrate 226 may form a drain region of the device 200. Although not shown explicitly in FIG. 2, the drain region formed by the substrate 226 may include a conductive contact similar to the source contact 206. The device 200 may also include a gate region that includes a gate contact 202 and a gate oxide 209. Each of the source, drain, and gate regions may include other layers or regions that are not explicitly shown in FIG. 2. Additionally, these contacts may also be referred to in this disclosure more generically as a “first,” “second,” and “third” contact to distinguish one contact from the other in a manner that is not specific to a transistor. For example, in this transistor implementation, the drain region may be referred to as a first contact region, the gate region may be referred to as a second contact region, and the source region may be referred to as a third contact region.

The internal regions of the device 200 may include a plurality of N-doped regions and/or P-doped regions. These regions may also be referred to as “pillars,” as these regions may extend from the silicon substrate 226 up to the top of the device 200. The device 200 may include a first N-type region 208 that extends orthogonally up from the silicon substrate 226 to the top of the device 200. The device 200 may also include a P-type region 210 that also extends orthogonally up from the silicon substrate 226 to the source region of the device 200. The device 200 may also include a second N-type region 212 that similarly extends orthogonally up from the silicon substrate 226 to the gate region. Note that the device 200 may also include additional contact regions, P-type regions (e.g., P-type region 214), and N-type regions (e.g., N-type region 216), some of which are illustrated in FIG. 2.

Typically, the width 220 of the P-type region 210 and the width 222 of the second N-type region 212 are approximately the same in standard super junction devices. Additionally, a doping level (N_{A}) of the P-type region 210 and a doping level (N_{D}) of the N-type region 212 are also equal. In order to function optimally, the charge should be balance between the second N-type region 212 and the P-type region 210 according to the following equation.

$${N}_{A} {W}_{p} = {N}_{D} {W}_{n} \qquad ( 1 )$$

With careful charge balancing between the N-type pillars in the P-type pillars in the device 200, these regions may completely deplete each other to form a depletion region throughout the bulk of the device 200. Full depletion increases the breakdown voltage of the device 200 significantly without lowering the doping concentrations. This allows the device to have very high doping concentrations in the N-type regions so long as the balance is maintained according to equation (1) above.

The breakdown voltage of the device 200 is also a function of the height 224 of the device 200. Typically, the greater the height 224 of the device 200, the higher the breakdown voltage of the device 200. However, manufacturing limitations have limited the height 224 of the device 200 due to aspect ratios of the features. Specifically, forming the device typically includes forming an N-type material on top of the silicon substrate 226. Trenches are then etched in the N-type region, leaving N-type mesas that include, for example, N-type region 208, N-type region 212, and so forth. The trenches are then filled with the P-type material to form the P-type regions, such as P-type region 210, P-type region 214, and so forth. Therefore, the aspect ratio of the trench fill limits the depth of the trench unless the width of the trench is increased. However, increasing the width of the trench increases the total size of the device 200. With shrinking device sizes, increasing the size of the device to increase the breakdown voltage is not a feasible option in most applications.

Typically, super junction devices are formed from silicon. As described above, the silicon substrate 226 may form the drain of the device 200. The first N-type region 208, the second N-type region 212, and so forth, may be formed from doped N-type silicon. Similarly, the first P-type region 210, the second P-type region 214, and so forth, may be formed from doped P-type silicon. The silicon material used to form the device 200 influences the breakdown voltage or voltage rating of the device 200.

For example, the device 200 in FIG. 2 may be rated as a 650 V device for a silicon device. The specifications for this 650 V device include a height 224 of about 40 μm. The width 220 of the P-type region 210 is about 2 μm (also referred to as a critical dimension or “CD”). This leads to an aspect ratio of 40/2=20 for a trench that is etched to form the P-type region 210. The pitch 228 is about 4 μm, which may be defined as the distance between centers of consecutive N-type regions. The aspect ratio of 20 has been found to be an acceptable feature size for current etch and fill operations for devices of this size. Increasing the aspect ratio beyond 20 at this size can cause problems when etching the trenches. Specifically, the trenches may erode at the top surface of the trench and may develop sloped sidewalls with a poorly defined bottom in the trench. Increasing the aspect ratio may also cause problems when filling the trenches. When depositing material in the trenches, the material may close off the trench at the top before the trench is filled throughout the height of the trench. This may cause voids or seams in the P-type regions that interfere with the operation of the device 200.

For example, doubling the breakdown voltage of the silicon 650 V device in FIG. 2 would require the height 224 of the device 200 to be doubled. However, doubling the height 224 of the device 200 would also double the aspect ratio of the trenches needed to form the P-type region 210. For example, when the height 224 of the device 200 is doubled to be about 80 μm, and the width 220 of the P-type region 210 is maintained at 2 μm, the aspect ratio doubles to be about 40. Etching a trench with an aspect this heigh tends not to generate a well-defined trench, and is difficult or impossible to fill without seams or voids. Therefore, the only option for maintaining a higher voltage for the device 200 is to increase the width or critical dimension of the trench accordingly. For example, to maintain an aspect ratio of 20, the width of the trench needs to double to 4 μm. This creates a pitch that is double the pitch of the 650 V device. This leads to a device that is double the width overall of the 650 V device 200. Doubling the size of a device is rarely a feasible option in most applications.

The embodiments described herein solve this problem of creating a high-voltage device by using wide bandgap materials instead of silicon. Additionally, the P-type regions are formed along the sidewalls of the trench etched in the N-type material. For example, the P-type regions may be grown as an epitaxial liner along the sidewalls of the trench. The sidewalls of the trench may also be doped using a plasma doping technique. Alternatively, a P-type layer may be formed on the sidewalls of the trench and an anneal process may perform a P-type region in the wide bandgap material through a diffusion process. In one embodiment, the height of the device may be doubled (e.g., to about 80 μm), and a trench with a width or critical dimension of 4 μm may be etched. This results in a trench having an aspect ratio of 20 as described above for the 650 V silicon device 200. However, contrary to the device 200 illustrated in FIG. 2, the trench may have a much smaller P-type region. This creates a very narrow P-type region (e.g., between 50 nm and 300 nm), and the resulting pitch between the N-type regions will still be 4 μm. This creates devices with a significantly higher breakdown voltage.

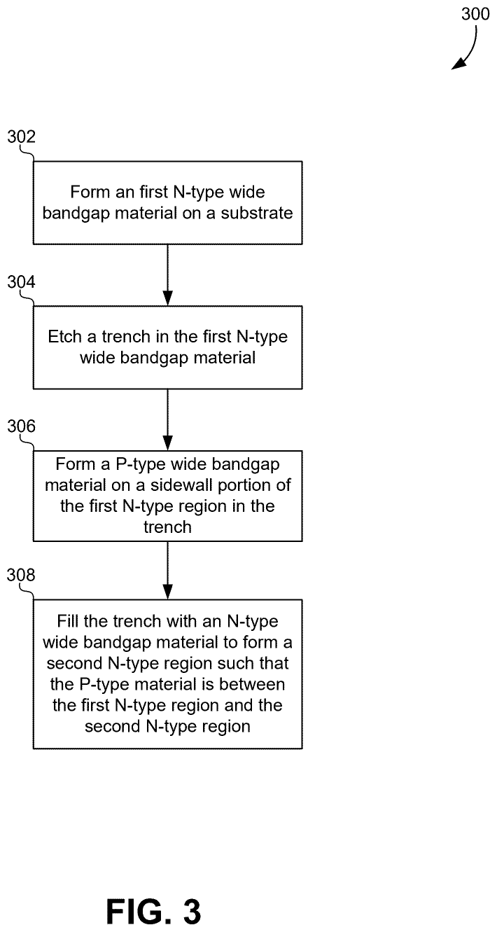

FIG. 3 illustrates a flowchart 300 of a method of forming a super junction device with wide bandgap materials, according to some embodiments. The method of flowchart 300 may be performed in one or more processing chambers, such as chambers incorporated in the system 100 described above. The method of flowchart 300 may or may not include one or more operations prior to the initiation of the method, including front-end processing, deposition, etching, polishing, cleaning, or any other operations that may be performed prior to the described operations. The method may also include a number of optional operations as denoted in the figure, which may or may not be specifically associated with some embodiments of methods according to the present technology.

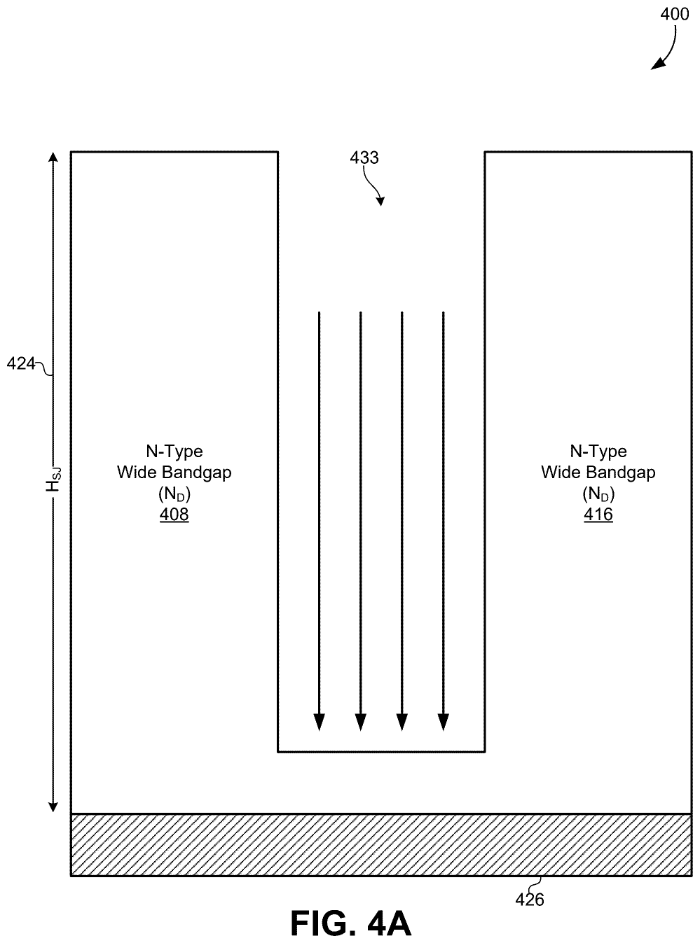

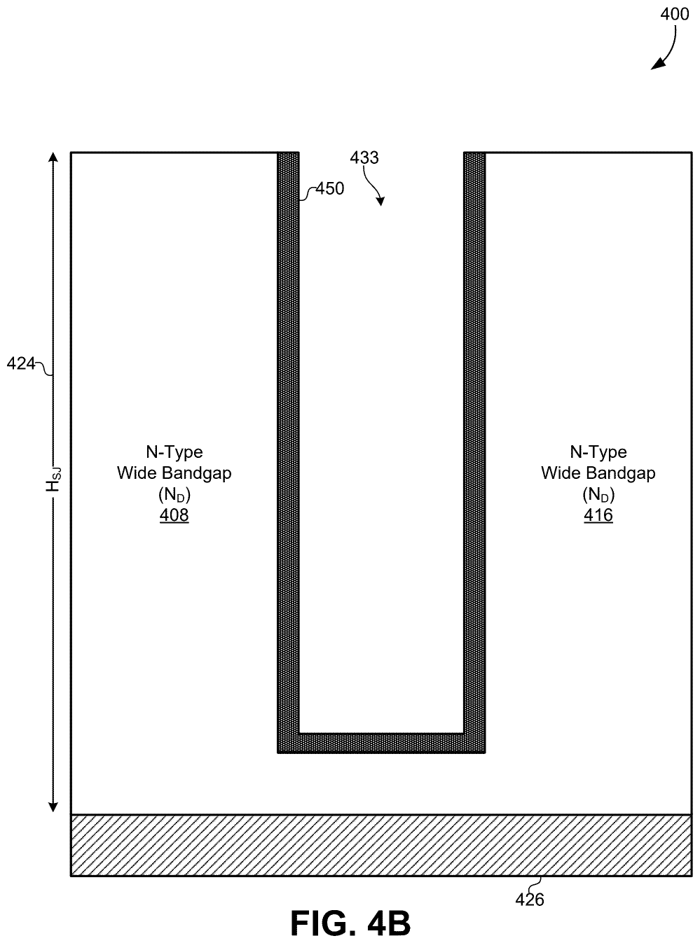

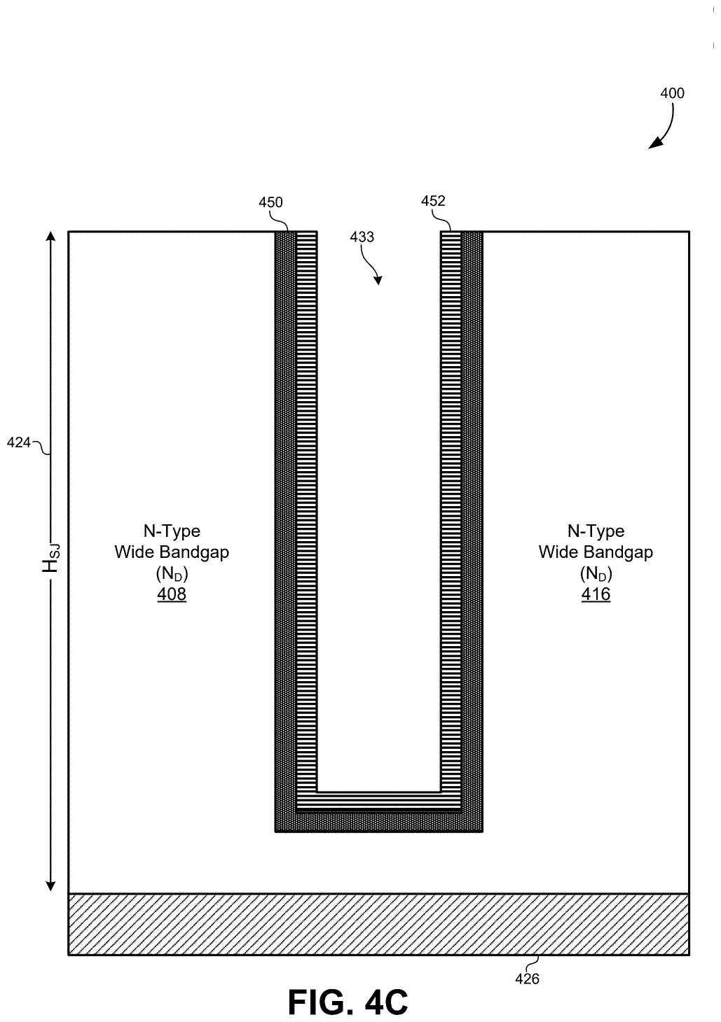

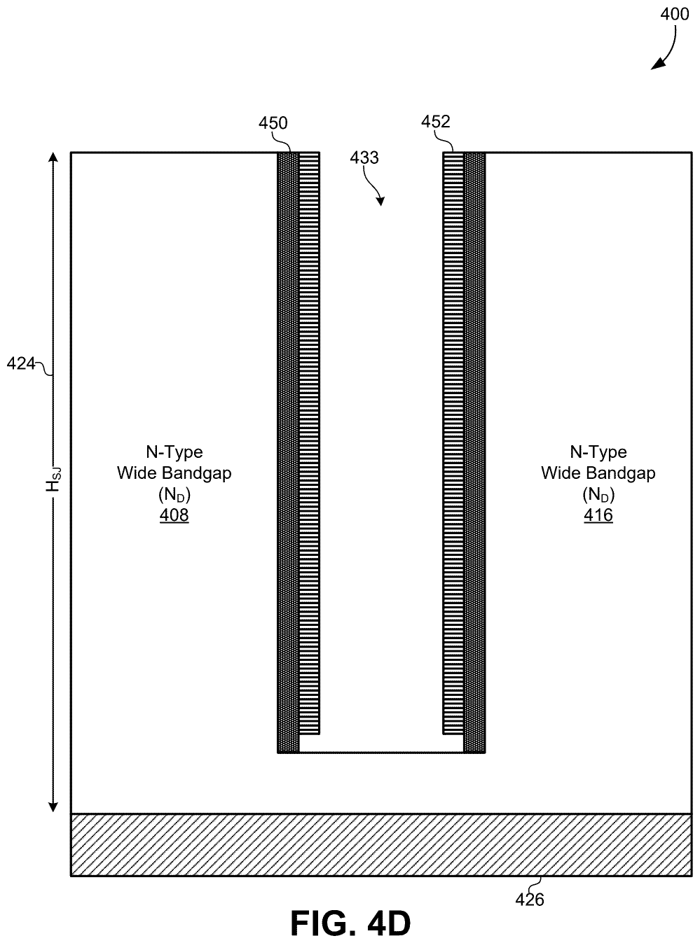

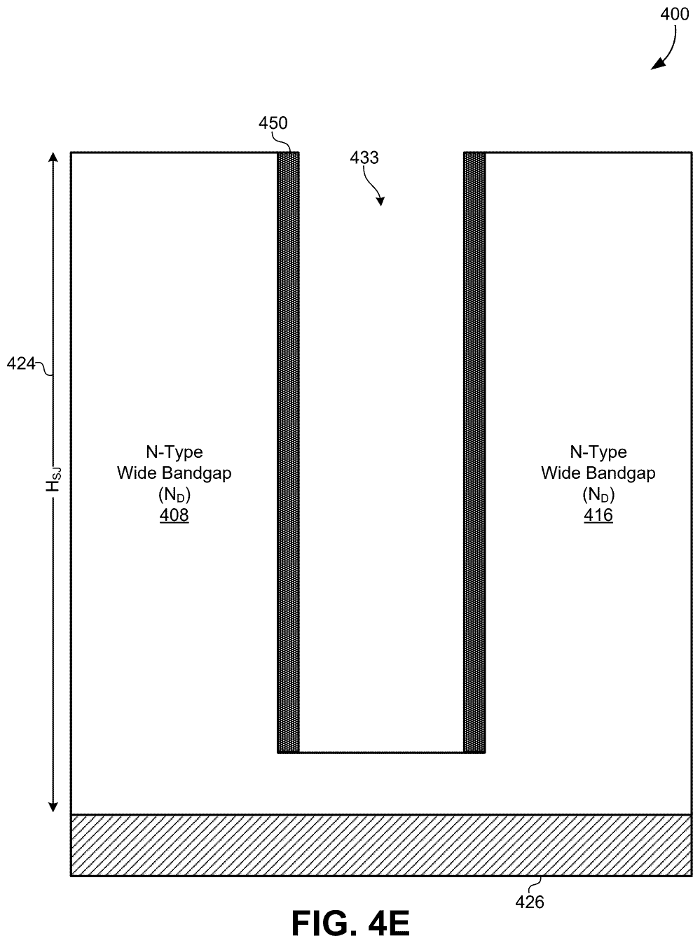

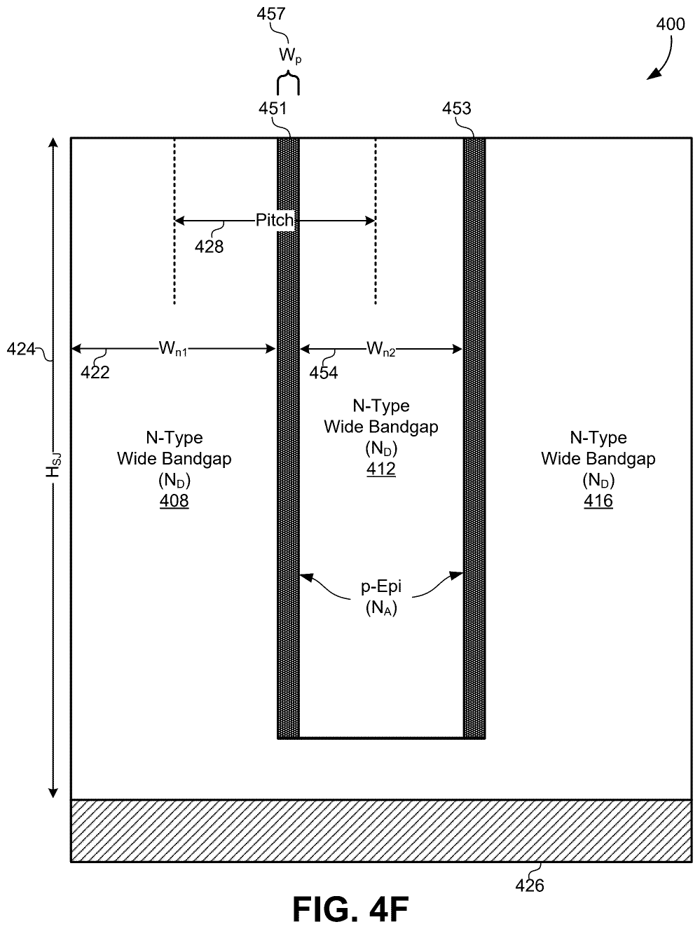

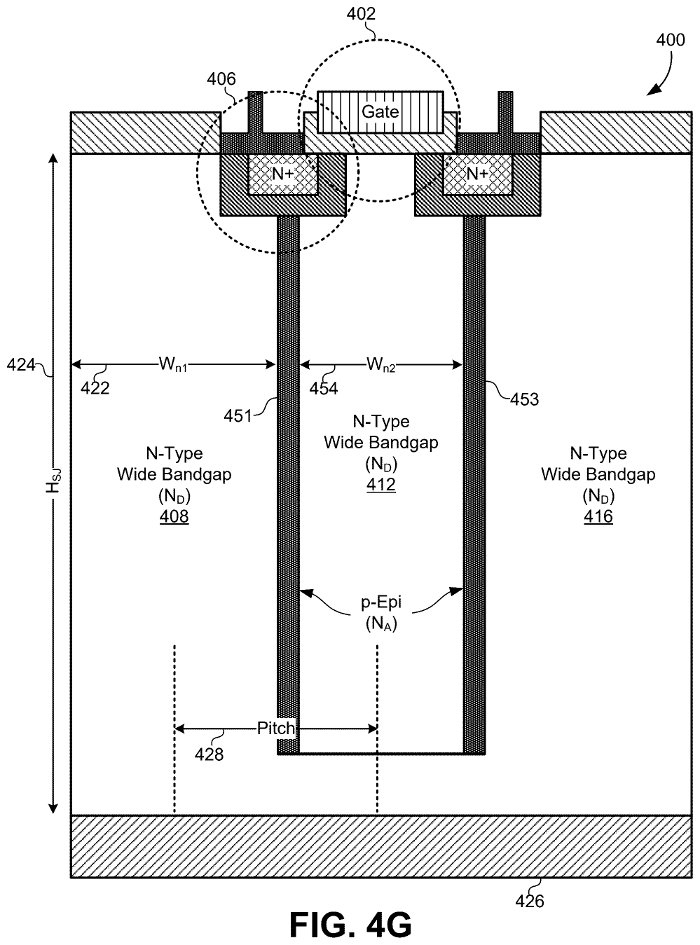

FIGS. 4A-4G illustrate incremental structures for forming the super junction device with a high breakdown voltage, according to some embodiments. The method of flowchart 300 describes operations shown schematically in FIGS. 4A-4G, the illustrations of which will be described in conjunction with the operations of this method. It is to be understood that the figures illustrate only partial schematic views with limited details, and in some embodiments a substrate may contain any number of semiconductor sections having aspects as illustrated in the figures, as well as alternative structural aspects that may still benefit from any of the aspects of the present technology.

The method of flowchart 300 may include forming a first N-type wide bandgap region over a substrate (302). As illustrated in FIG. 4A, the structure 400 may include a substrate 426. The substrate 426 may have a substantially planar surface or an uneven surface in various embodiments. The substrate 426 may be a form from a wide bandgap material. The term “wide bandgap” material is a recognized term in the field of semiconductor technology. These materials may also be known as “WBGs” for short. By definition, a wide bandgap semiconductor are semiconductor materials that have a larger bandgap than conventional silicon semiconductors. More specifically, conventional silicon semiconductors have a bandgap in the range of 0.6 eV to 1.5 eV. In contrast, wide bandgap materials have bandgaps that are greater than 2.0 eV with electric properties that fall between those of conventional silicon semiconductors and insulators. It is been discovered that wide bandgap materials may allow a super junction device to operate at a much higher voltage than conventional semiconductors such as silicon and gallium arsenide. Specific examples of why bandgap semiconductors that may be used with the embodiments described herein include silicon carbide (SiC), gallium nitride (GaN), aluminum gallium nitride (AlGaN), and so forth.

In this example, the substrate 426 may be formed from a highly doped wide bandgap material, such as N⁺ SiC, N⁺ GaN, N⁺ AlGaN, or the like. The substrate 426 may have various dimensions, such as 200 mm or 300 mm diameter wafers, as well as rectangular or square panels. The substrate 426 may be disposed within the processing region of the semiconductor processing chamber. Although shown as a planar substrate, it is to be understood that substrate 426 is included merely to represent an underlying structure, which may include any number of layers or features on a wafer or other substrate, and over which structures as described below may be formed.

Above the substrate 426, the structure 400 may include a first N-type wide bandgap material. The first N-type wide bandgap material may be disposed along at least a portion or all of the substrate 426. The first N-type wide bandgap material may be N-type SiC, GaN, AlGaN, or the like, and which may be doped with phosphorous, arsenic, a combination of both, or other similar materials. The first N-type wide bandgap material may form the first N-type wide bandgap region 408, although the mesa or pillar of the first N-type wide bandgap region 408 (and possibly other N-type wide bandgap regions 416) may not become apparent until after a trench is etched in the following operation. The height 424 of the first N-type wide bandgap material and the subsequent first N-type wide bandgap region 408 may be greater than or about 40 μm, between about 40 μm and about 50 μm, between about 50 μm and about 60 μm, between about 60 μm and about 70 μm, between about 70 μm and about 80 μm, greater than or about 80 μm, and so forth. Other embodiments may include a first N-type wide bandgap region 408 that is less than about 40 μm, which may be used to form super junction devices with a smaller overall width. Additionally, the use of the why bandgap materials may allow the height 424 to be reduced significantly. For example, silicon carbide devices and other similar devices may have a height 424 that is between about 40 μm and about 30 μm, between about 30 μm and about 20 μm, between about 20 μm and about 10 μm, or less than about 10 μm, depending on the desired breakdown voltage. The height 424 may also be any combination of ranges described above (e.g., greater than 60 μm, between about 20 μm and about 60 μm, etc.) or any specific value mentioned in the ranges above (e.g., about 80 μm). Other embodiments may also include a first N-type wide bandgap region 408 that is greater than or about 90 μm, greater than or about 100 μm, and so forth, depending on the desired voltage characteristics of the super junction device.

In some embodiments, to facilitate patterning of the first N-type wide bandgap material, hard masks, photoresists, or any other mask materials may be disposed along the first N-type wide bandgap material. For example a first mask may be formed over the first N-type wide bandgap material, and a second mask may be formed over the first mask. In some embodiments, either or both masks may be any number of materials to promote structural formation, such as oxides, nitrides, carbides, or some combination of materials. For example, the first mask may be or include silicon nitride, and the second mask may be or include silicon oxide, or some other mask material. It is contemplated that a singular mask may be provided over the first N-type wide bandgap material and the embodiment depicted in FIG. 4A is merely one example structure 400.

The method of flowchart 300 may also include etching a trench 433 in the first N-type wide bandgap material (304). As shown in FIG. 4A, a pattern may be etched or formed through the first mask and/or the second mask to form features, such as the trench 433. The trench 433 may be etched through the first mask and/or the second mask using any etching processes and any etching reagents. In some embodiments, the etching may completely remove the second mask as a pattern is transferred into the underlying N-type wide bandgap material.

The etching of the first N-type wide bandgap material may form one or more trenches in the material. The trench 433 may be formed to a depth of less than about 10 μm, between about 10 μm and about 20 μm, between about 20 μm and about 30 μm, between about 30 μm and about 40 μm, between about 40 μm and about 50 μm, between about 50 μm and about 60 μm, between about 60 μm and about 70 μm, between about 70 μm and about 80 μm, between about 80 μm and about 90 μm, and/or greater than about 90 μm. The height depth of the trench 433 may also be any combination of ranges described above (e.g., greater than 60 μm, between about 20 μm and about 60 μm, etc.) or any specific value mentioned in the ranges above (e.g., about 75 μm). As illustrated in FIG. 4A, the depth of the trench 433 may not extend all the way down to the top surface of the substrate 426. This leaves a thin layer of N-type wide bandgap material at the bottom of the device along the substrate 426, which may have some beneficial properties. For example, current spikes or overshoots may occur when switching the device at high frequencies. A buffer layer of N-type wide bandgap material at the bottom of the trench 433 may prevent these surges in current. Although not shown explicitly in FIG. 4A, some embodiments of the trench 433 may extend all the way down to a top surface of the substrate 426. In some embodiments, the trench 433 may also extend below a top surface of the substrate 426 such that the trench 433 penetrates the substrate 426. This provides a surface from which epitaxial wide bandgap material may be grown from the substrate 426 when filling the trench 433. Therefore, the depth of the trench 433 may correspond to any of the heights described above for the first N-type wide bandgap region 408 plus/minus 5%, 10%, 15%, 20%, and/or 25%. For example, the trench 433 may have a depth of between about 75 μm and 85 μm for a device height 424 of about 80 μm.

Note that the height 424 of the structure 400 may also be reduced to reduce the breakdown voltage proportionally, since the breakdown voltage is linearly related to the height 424 of the structure 400. However, the breakdown voltage of the device is also related to the material type. For example, a silicon carbide device may have a breakdown voltage of about 6000 V, where a silicon device of the same height would have a breakdown voltage of about 600 V. When using wide bandgap materials, the breakdown voltage range of the device may be between about 600 V and about 1300 V, between about 1300 V and about 2000 V, between about 2000 V and about 5000 V, between about 5000 V and about 10,000 V, between about 10,000 V and about 20,000 V, between about 20,000 V and about 30,000 V, between about 30,000 V, and about 50,000 V, between about 50,000 V and about 75,000 V, between about 75,000 V and about 100,000 volts, and/or greater than about 100,000 V. The breakdown voltage of the structure 400 may also include any combination of ranges described above (e.g., greater than about 13,000 V, between about 20,000 V and about 40,000 V, etc.) or may include any single value contained in the ranges described above (e.g., about 650 V).

The trench 433 may have an aspect ratio, or a depth-to-width ratio less than or about 50, less than or about 40, less than or about 30, less than or about 25, less than or about 20, less than or about 15, less than or about 10, or less. Additionally the trench 433 may be formed to a width of greater than or about 1.5 μm, greater than or about 2.0 μm, greater than or about 2.5 μm, greater than or about 3.0 μm, greater than or about 3.5 μm, greater than or about 4.0 μm, greater than or about 4.5 μm, greater than or about 5.0 μm, greater than or about 6.0 μm, greater than or about 7.0 μm, greater than or about 8.0 μm, greater than or about 9.0 μm, greater than or about 10.0 μm, or greater. The trench 433 may also be formed to a width of between about 1.5 μm in about 2.0 μm, between about 2.0 μm and about 2.5 μm, between about 2.5 μm in about 3.0 μm, between about 3.0 μm and about 3.5 μm, between about 3.5 μm and about 4.0 μm, between about 4.0 μm and about 4.5 μm, between about 4.5 μm, and about 5.0 μm, between about 4.5 μm and about 6.0 μm, and so forth. The width of the trench 433 may also include any combination of ranges discussed above.

While conventional methods may strive for etching higher aspect ratio trenches to allow for narrower and deeper P-type regions to be formed by filling the trench 433, forming trenches with higher aspect ratios may make structural formation more difficult. Not only may it be difficult to etch high aspect ratio trenches with consistent diameters, but it may also be difficult to backfill these trenches uniformly with the P-type material. Instead, the P-type material may have seams and/or voids present due to pinch off at the top of the feature during fill. Conversely, the embodiments described herein may counterintuitively allow for relaxing the width of the trench 433 to produce smaller pitch structures or higher aspect ratio structures, which may allow for more uniform etching and subsequent backfill. Further, with an increased width of the trench 433, deeper etching of the N-type wide bandgap material may be afforded. As an additional benefit of deeper etching, and therefore deeper structures of material, increased breakdown voltages for power devices produced by the present technology may be afforded compared to conventional methods and technology.

The method of flowchart 300 may include forming a P-type material on a sidewall portion of the first N-type wide bandgap region 408 in the trench 433 (306). FIG. 4B illustrates forming a P-type liner 450 on a sidewall portion of the first N-type wide bandgap region 408 in the trench 433, according to some embodiments. The deposition or formation may be performed in any number of ways, and in some embodiments the material may be formed conformally about the feature. The P-type liner 450, which may be a P-type wide bandgap material, for example, may be deposited by atomic layer deposition, grown epitaxially, or produced by any number of other processes to produce conformal coverage about the trench 433. By having trenches characterized by wider width, the coverage may be uniform despite the greater depth of the trench 433. The P-type liner 450 may be characterized by a thickness of between about 50 nm and about 100 nm, between about 100 nm and about 150 nm, between about 150 nm and about 200 nm, between about 200 nm and about 250 nm, between about 250 nm and about 300 nm, greater than or about 300 nm, and so forth. The P-type liner 450 may also be characterized by a thickness of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, or less. The P-type liner 450 may be any wide bandgap material doped with boron or other P-type similar materials. In some embodiments, the P-type liner 450 may include SiC, GaN, AlGaN, or other similar materials.

The P-type liner 450 may substantially cover the sidewall portion of the first N-type wide bandgap region 408 in the trench 433. In some embodiments, the P-type liner 450 may also be formed on the bottom of the trench 433. The P-type liner 450 may be free of seams and/or voids based on the conformal coverage about the structure, even to a depth of several hundred nanometers, which may provide large improvements on performance for final devices compared to conventional technologies that have reduced or incomplete coverage at greater depths, as well as seam or void formation. However, it is contemplated that some pores may be present in the P-type liner 450, depending on the formation and thickness.

As stated above, alternate approaches may be used to forming the P-type material on the sidewall portion of the first N-type wide bandgap region 408 in the trench 433 (306). For example, some embodiments may deposit a layer of P-type material over the sidewalls of the trench, then use a thermal anneal process to cause the P-type dopants from the P-type material to diffuse into the first N-type wide bandgap region 408. Alternatively, some embodiments may use a plasma doping process to place P-type dopants in the sidewalls of the trench 433, after which a thermal anneal process may cause the P-type dopants from the plasma doping to diffuse into the first N-type wide bandgap region 408. Note that in contrast to other methods, this method forms the P-type region directly in the first N-type wide bandgap region. This may be contrasted with other methods that perform or grow a P-type liner over the sidewalls of the trench, where the P-type liner operates as the P-type region of the super junction device. Instead P-type dopants may be implanted and/or diffused in the sidewall of the trench 433 such that the overall size of the first N-type wide bandgap region 408 shrinks by the resulting size of the P-type region.

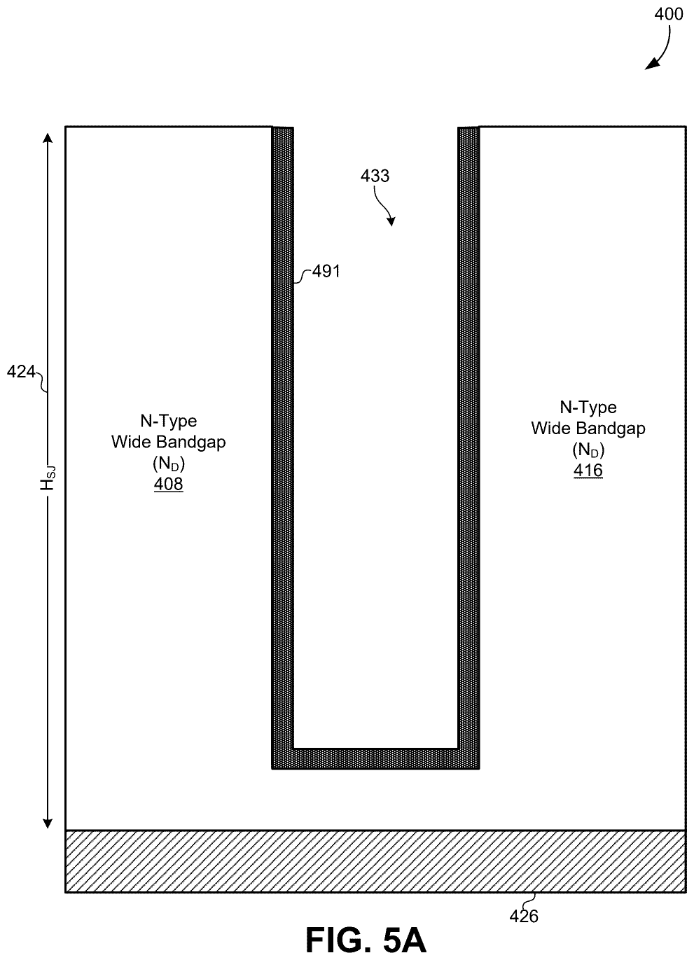

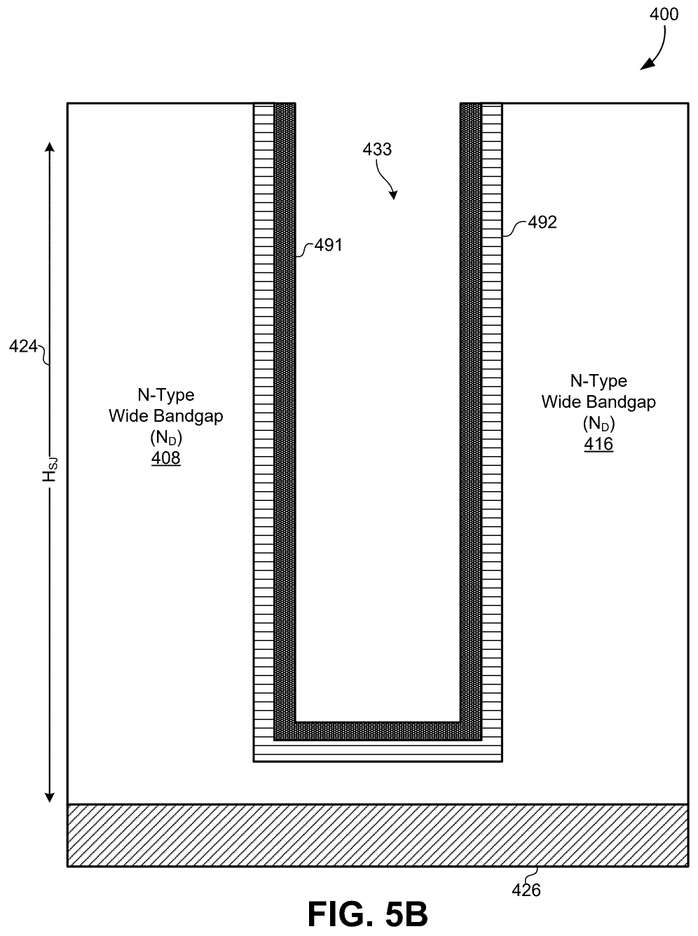

FIG. 5A illustrates forming a P-doped layer 491 on a sidewall of the trench 433 comprising the first N-type wide bandgap region, where the P-doped layer comprises a P-type dopant, according to some embodiments. This process may represent a solid-state diffusion doping process. The P-doped layer may include any dielectric or other material that is doped with the P-type dopant. For example, some embodiments may use a dielectric such as silicon oxide that is doped with boron to a very high concentration. Other embodiments may use doped silicon nitride, Borophosphosilicate glass (BPSG), or other similar materials. The P-doped layer may be doped with a concentration of P-dopants that is between about 5% and about 10%, between about 10% and about 15%, between about 15% and about 20%, between about 20% and about 25%, between about 25% and about 30%, or greater. The concentration of P-dopants may be any combination of the ranges disclosed above (e.g., between about 5% and about 20%, greater than about 15%, etc.). The concentration of P dopants may also be any individual value in the ranges disclosed above (about 15%).

The p-doped layer 491 may be deposited or formed using deposition techniques such as chemical-vapor deposition (CVD) on the sidewall of the trench 433. In some embodiments the material may be formed conformally about the feature. The P-doped layer 491 may also be deposited by atomic layer deposition (ALD) or produced by any number of other processes to produce conformal coverage about the trench 433, such as plasma-enhanced CVD (PECVD). By having trenches characterized by a wider width, the coverage may be uniform despite the greater depth of the trench 433. The P-doped layer 491 may be characterized by a thickness of between about 50 nm and about 100 nm, between about 100 nm and about 150 nm, between about 150 nm and about 200 nm, between about 200 nm and about 250 nm, between about 250 nm and about 300 nm, greater than or about 300 nm, and so forth up to 1 μm. The P-doped layer 491 may also be characterized by a thickness of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, or less.

The thickness of the P-doped layer 491 may also include any combination of the ranges described above (e.g., between about 100 nm and about 200 nm, etc.). The thickness of the P-doped layer 491 may also include any single value within the ranges described above (e.g., about 200 nm).

The P-doped layer 491 may substantially cover the sidewall portion of the first N-type wide bandgap region 408 in the trench 433. In some embodiments, the P-doped layer 491 may also be formed on the bottom of the trench 433. The P-doped layer 491 may be free of seams and/or voids based on the conformal coverage about the structure, even to a depth of several hundred nanometers, which may provide large improvements of performance for super junction devices compared to conventional technologies that have reduced or incomplete coverage at greater depths, as well as seam or void formation. However, it is contemplated that some pores may be present in the P-doped layer 491, depending on the formation and thickness.

FIG. 5B illustrates annealing the P-doped layer 491 sufficiently to cause the P-type dopant to diffuse into the first N-type wide bandgap region 408, thereby forming a P-type region wide bandgap 492 in the first N-type wide bandgap region 408, according to some embodiments. The thermal anneal process may be performed for a number of different reasons. First, the thermal anneal may diffuse the dopant deeper into the first N-type wide bandgap region 408 as illustrated in FIG. 5B. Additionally, the thermal anneal may activate the dopants and cause a conformal, ultra-thin P-type wide bandgap region 492.

The thermal anneal may be carried out at a high temperature in an inert atmosphere. For example, a gas delivery system of the processing chamber may deliver an inert gas to the processing volume, such as nitrogen or argon gas. The high temperatures of the thermal anneal process may range from between about 500° C. to about 600° C., between about 600° C. to about 700° C., between about 700° C. to about 800° C., between about 800° C. to about 900° C., between about 900° C. to about 1000° C., between about 1000° C. to about 1100° C., between about 1100° C. to about 1200° C., of higher. The temperature of the thermal anneal process may also include any combination of these ranges (e.g., between about 700° C. and about 1100° C.) or may include any single value in these ranges (e.g., about 800° C.).

The time of the thermal anneal process may be adjusted and/or determined based on a depth of diffusion and the relative concentration of the P-dopant in the P-type wide bandgap region 492. For example, longer thermal anneal processes may cause the depth of diffusion to be greater. The diffusion depth may range from between about 10 nm to about 50 nm, between about 50 nm and about 100 nm, between about 100 nm and about 150 nm, between about 150 nm and about 200 nm, between 200 nm and about 400 nm, between about 400 nm and about 600 nm, between about 600 nm and about 800 nm, and/or between about 800 nm and 1 μm. The diffusion depth may also include any combination of these ranges (e.g., between about 100 nm about 200 nm) or any individual value in these ranges (e.g., about hundred 50 nm).

As described above, the charge balancing between the first N-type wide bandgap region 408 and the P-type wide bandgap region 492 may be based on the width of the regions and the relative doping concentrations. Since the width of the P-type wide bandgap region 492 will be relatively narrow (e.g., about 10% the width of the first N-type wide bandgap region 408), the doping concentration of the P-type wide bandgap region 421 may be relatively high in comparison to the first N-type wide bandgap region 408. For example, for a doping concentration of about 3e15 dopants/cm³ in the first N-type wide bandgap region 408, the doping concentration of the P-type wide bandgap region 492 may range from between about 5e15 dopants/cm³ to about 5e17 dopants/cm³ or higher, depending on the width. The doping concentration and the width of the P-type wide bandgap region 492 (e.g., the diffusion depth) may be adjusted to achieve the desired charge balancing for the super junction device.

After the thermal anneal process, the p-doped layer 491 may be removed from the trench 433. This removal process may use a selective removal process that causes the p-doped layer 491 to be removed without removing any of the underlying material. For example, wet etch techniques may be used to remove the p-doped layer 491 without significantly removing any of the P-type wide bandgap region 492. At this stage, a P-type wide bandgap region 492 has been formed inside the N-type wide bandgap material that surrounds the trench 433. The vertical pillars of the P-type wide bandgap region 492 are significantly thinner than can be achieved using traditional etch and fill processes.

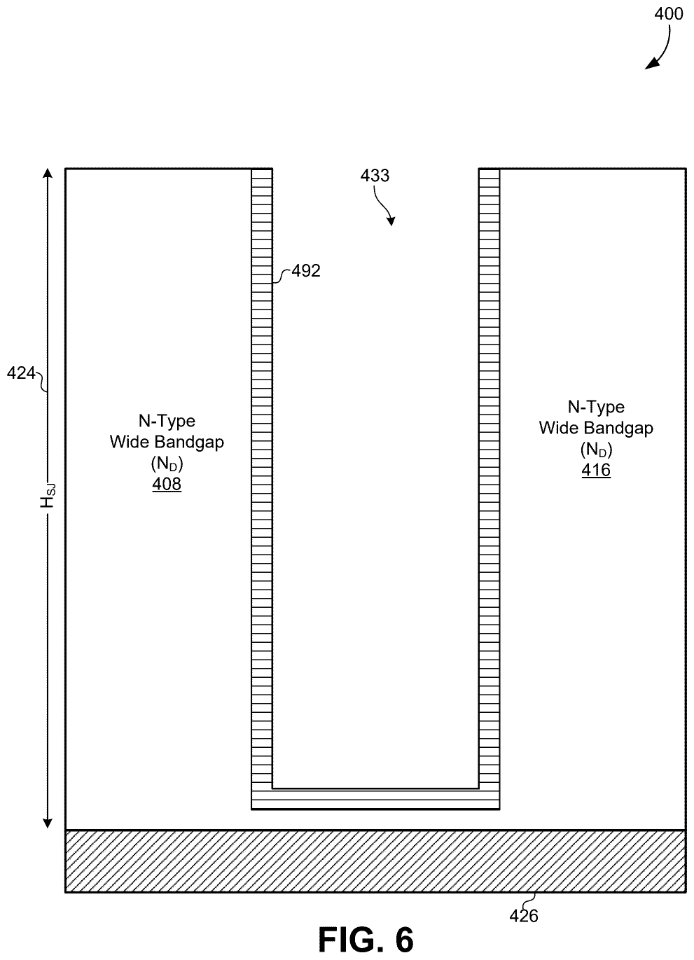

Another alternate technique may be used in order to produce the P-type region in the N-type wide bandgap material of the trench. FIG. 6 illustrates how the P-type wide bandgap region 492 may be formed in the N-type wide bandgap material using a plasma doping (PLAD) technique, according to some embodiments. PLAD may offer the advantage of high-dose doping that is well-suited for sidewall doping solutions at high volumes. This technique may accelerate ions from the plasma by applying a high-voltage pulsed DC or direct-wave DC power supply and targeting the ions at the substrate, including the sidewalls of the trench 433. PLAD has been discovered to work well in high-aspect-ratio features, such as the trench 433.

While normal ion beam implantation techniques accelerate ions into a crystal lattice structure, then anneal the material to reform the crystal, a plasma doping process generates ions and radicals when the plasma is formed. The surface of the structure 400 may then be bombarded with the plasma particles, including the sidewalls of the trench 433. The dopants that are implanted with the PLAD process may result in a very shallow, but also very concentrated doping at the surface of the sidewalls of the trench 433. Specifically, the depth of diffusion may be tightly controlled using the PLAD process in comparison to other implant processes. Additionally, the doping depth may be more abrupt when using PLAD compared to other techniques, which usually exhibit a tailing-off of the doping concentration as the depth increases. As illustrated in FIG. 6, the P-type dopants may be implanted directly into the sidewalls of the trench 433, as well as the bottom of the trench 433.

As discussed above in relation to FIG. 5B, a thermal anneal process may also be carried out on the structure 400 that used the PLAD process. For example, a thermal anneal of between about 700° C. and about 1100° C. may be performed to increase the diffusion depth of the dopants and reform the lattice of the material. The thermal anneal may be carried out using any of the parameters discussed above.

At this stage, a region of P-type material has been formed on the sidewalls of the trench 433 using epitaxial growth, diffusion, and/or doping as described in detail above. Regardless of the method used to form the P-type material, this portion of the structure 400 will now be referred to as a P-type liner 450 in the subsequent figures and/or discussion.

FIG. 4C illustrates the formation of a passivation layer 452 as part of an optional operation that may be added to the method of flowchart 300 in some embodiments. The passivation layer 452 may be formed by providing an oxygen-containing precursor to the processing region. The oxygen-containing precursor may be any number of precursors that may oxidize the P-type liner 450. As non-limiting examples, the oxygen-containing precursor may be or include diatomic oxygen, ozone, nitrous oxide, nitric oxide, sulfur dioxide or any other oxygen-containing precursors which may be delivered with or without plasma enhancement, and may be used to oxidize a depth of the existing material, or may be delivered with any other precursor, such as a silicon-containing precursor to deposit an oxide layer. The passivation layer 452 may be formed by using any deposition or growth method. The oxygen-containing material in the passivation layer 452 may oxidize and passivate at least a portion of the P-type liner 450. The passivation layer 435 may serve to protect the P-type liner 450 during subsequent etch operations.

FIG. 4D illustrates the result of a directional etch to remove the P-type liner 450 from the bottom of the trench 433. The portion of the P-type liner 450 that is removed may be located at a bottom of the trench 433. In addition to the portion of the P-type liner 450 that is removed, a portion of the passivation layer 452 may also be removed. The portion of the passivation layer 452 that is removed may be located at a bottom of the trench 433. In some embodiments, removing the portion of the P-type liner 450 may include an anisotropic etching process, such as a reactive-ion etching operation or any other directional dry etch process. For example, the method of flowchart 300 may include applying bias power to etch the bottom of the passivation layer 452 and/or the P-type liner 450. The etching of the passivation layer 452 may be due to a sputtering of the oxide in the passivation layer 452, while a more chemical-based removal may occur through the p-type material, or vice versa. The bottom of the passivation layer 452 may be sputtered and removed at a faster rate than the sidewalls of the passivation layer 452 due to the anisotropicity of the etch. Therefore, this operation may remove the P-type liner 450 and the passivation layer 452 from the bottom of the trench 433 while leaving the P-type liner 450 and the passivation layer 452 along the sidewall portion of the trench 433. As illustrated in FIG. 4D, this etch process may expose the N-type wide bandgap material at the bottom of the trench 433. Therefore, the etch need not go all the way down to the substrate 426. However, in other embodiments, the etch may expose the surface of the substrate 426 at the bottom of the trench 433, and may even etch into the substrate 426.

FIG. 4E illustrates the removal of the remaining portion of the passivation layer 452, according to some embodiments. The method of flowchart 300 may optionally include removing the remaining portion of the passivation layer 452. The portion of the passivation layer 452 that is removed may be located along sidewalls of the trench 433 and overlying P-type liner 450. In some embodiments, removing the portion of the passivation layer 452 may include, as one non-limiting example, a wet etching operation using any wet etching reagent(s), such as halogen-containing materials. However, it is contemplated that other forms of etching may alternatively or additionally be utilized including dry etch processes.

The remaining P-type liner 450 may be present on the sidewalls of the trench 433. The P-type liner 450 may be characterized by an aspect ratio of greater than or about 50, greater than or about 100, greater than or about 150, greater than or about 200, greater than or about 250, greater than or about 300, greater than or about 350, greater than or about 400, or more. With taller, narrower features than conventional methods, super junction devices formed using these structures may be characterized by reduced on-resistance due to the separation distances between N-type wide bandgap regions, and may be characterized by increased breakdown voltages due to the depth and uniformity of the P-type pillars formed.

The method of flowchart 300 may include filling the trench 433 with an N-type wide bandgap material to form a second N-type wide bandgap region 412 such that the P-type liner 450 is between the first N-type wide bandgap region 508 and the second N-type wide bandgap region 412 (306). FIG. 4F illustrates the formation of the second N-type wide bandgap region 412, according to some embodiments. The second N-type wide bandgap region 412 may fill the trench 433 by backfilling the internal region of the trench 433 between the sidewalls on which the P-type liner 450 has been formed. The second N-type wide bandgap region 412 may fill the trench 433 free of any voids and without intermittent etching based on the increased width that may be afforded from the initial trench formation (e.g., about 4 μm). The second N-type wide bandgap region 412 may be the same material as the first N-type wide bandgap region 408. Together, the N-type wide bandgap region 408 and the second N-type wide bandgap region 412 may at least partially surround the P-type liner 450. The P-type liner 450 may now be referred to as a P-type wide bandgap region 451, 453 in the super junction device. The trench 433 may be filled with N-type wide bandgap material through an epitaxial growth process. For example, the exposed substrate 526 may provide a base for epitaxially growing wide bandgap material up from the bottom of the trench 433 to fill the trench 433.

A ratio of a width of the second N-type wide bandgap region 412 to a width of the P-type wide bandgap region 451 may be greater than or about 15, and may be greater than or about 20, greater than or about 22, greater than or about 24, greater than or about 26, greater than or about 28, greater than or about 30, or more. The ratio between the two materials may lead to a reduction of on-resistance in subsequent devices produced with these structures, as previously discussed. Alternatively stated, a width 457 of the P-type wide bandgap region 451 may be less than or about 10% of a combined width of the P-type wide bandgap region 451 and the second N-type wide bandgap region 412. The width 457 of the P-type wide bandgap region 451 may also be less than or about 9%, less than or about 8%, less than or about 7%, less than or about 6%, less than or about 5%, and so forth, of this combined width. For example, a P-type wide bandgap region 451 with a width 457 of 200 nm may be formed with a second N-type wide bandgap region 412 with a width 454 that is 3.8 μm in a trench that is 4.0 μm wide and 80 μm high.

Additional operations may include removing a portion of the N-type wide bandgap material and any remaining mask material by planarizing the structure, such as with a chemical-mechanical polishing operation. The method may also optionally include forming the remaining contact regions for the structure 400. FIG. 4G illustrates the structure 400 with contact regions, according to some embodiments. The structure 400 may include a gate region 402 and/or a source region 406 to complement a drain region formed by the substrate 426. The P-type wide bandgap region 451 may be disposed between the first N-type wide bandgap region 408 and the second N-type wide bandgap region 412 with a much thinner width. To maintain the proper charge balance, the doping level of the P-type wide bandgap region 451 may be increased accordingly. The doping level of the first N-type wide bandgap region 408 and/or the second N-type wide bandgap region 412 may be, for example, between about 1e14 dopants/cm³ and about 1e16 dopants/cm³. The doping level of the P-type wide bandgap region 451 may be greater than or about 8 times, greater than or about 9 times, greater than or about 10 times, and so forth, of the doping level of the first N-type wide bandgap region 408.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a pillar” includes a plurality of such pillars, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A super junction device comprising:
a first N-type wide bandgap region extending up from a substrate, wherein the substrate forms a first contact region for the device;
a second N-type wide bandgap region extending up from the substrate to a second contact region of the device; and
a P-type wide bandgap region disposed between the first N-type wide bandgap region and the second N-type wide bandgap region, wherein a width of the P-type wide bandgap region comprises less than or about 10% of a combined width of the P-type wide bandgap region and the first N-type wide bandgap region.

2. The super junction device of claim 1, wherein the first N-type wide bandgap region comprises a wide bandgap material with a bandgap greater than 2.0 eV.

3. The super junction device of claim 1, wherein the width of the P-type wide bandgap region is less than or about 200 nm.

4. The super junction device of claim 1, wherein:
the first contact region comprises a drain of a super junction transistor; and
the second contact region comprises a gate of the super junction transistor.

5. The super junction device of claim 4, wherein the super junction transistor has a breakdown voltage of greater than or about 13,000 V.

6. The super junction device of claim 1, wherein the combined width of the P-type wide bandgap region and the second N-type wide bandgap region is less than or about 4 μm.

7. The super junction device of claim 1, wherein a doping concentration of the P-type wide bandgap region is higher than a doping concentration of the second N-type wide bandgap region.

8. A super junction device comprising:
a wide bandgap substrate forming a drain region for the device;
a gate region;
a source region;
an N-type wide bandgap region extending from the wide bandgap substrate up to the gate region; and
a P-type wide bandgap region extending up to the source region, wherein the device has a pitch between centers of N-type wide bandgap regions that is equal to a width of a trench etched to form the P-type wide bandgap region and an adjacent N-type wide bandgap region.

9. The super junction device of claim 8, wherein the N-type wide bandgap region comprises SiC, GaN, or AlGaN.

10. The super junction device of claim 8, wherein an aspect ratio of an area occupied by the N-type wide bandgap region and the P-type wide bandgap region is less than or about 20.

11. The super junction device of claim 8, wherein a width of an area occupied by the N-type wide bandgap region and the P-type wide bandgap region is less than or about 4 μm.

12. A method of forming a super junction device, the method comprising:
forming a first N-type wide bandgap material on a wide bandgap substrate;
etching a trench in the first N-type wide bandgap material, wherein the trench forms at least a first N-type wide bandgap region from the first N-type wide bandgap material;
forming a P-type wide bandgap region along a sidewall of the trench on or in the first N-type wide bandgap region; and
filling the trench with a second N-type wide bandgap material to form a second N-type wide bandgap region such that the P-type wide bandgap region is between the first N-type wide bandgap region and the second N-type wide bandgap region.

13. The method of claim 12, wherein the trench is etched above a top surface of the wide bandgap substrate such that the top surface of the wide bandgap substrate is not exposed at a bottom of the trench and the P-type wide bandgap region does not contact the wide bandgap substrate.

14. The method of claim 12, wherein forming the P-type wide bandgap region comprises epitaxially growing a P-type liner along the sidewall of the trench.

15. The method of claim 14, wherein forming the P-type wide bandgap region comprises:
performing a plasma doping (PLAD) operation on the sidewall of the trench, wherein the PLAD operation dopes the sidewall with a P-type dopant;
annealing the sidewall sufficiently to cause the P-type dopant to diffuse into the first N-type wide bandgap region, thereby forming the P-type wide bandgap region in the first N-type region.

16. The method of claim 12, wherein forming the P-type wide bandgap region comprises:
forming a P-doped layer on a sidewall of the trench comprising the first N-type wide bandgap region, wherein the P-doped layer comprises a P-type dopant;
annealing the P-doped layer sufficiently to cause the P-type dopant to diffuse into the first N-type wide bandgap region, thereby forming the P-type wide bandgap region in the first N-type region.

17. The method of claim 16, wherein the P-doped layer comprises boron-doped silicon oxide, boron-doped silicon nitride, or borophosphosilicate (BPSG) glass.

18. The method of claim 12, further comprising performing a directional etch to remove any P-type wide bandgap material from a bottom of the trench while leaving the P-type wide bandgap region along the sidewall of the trench.

19. The method of claim 12, wherein a doping concentration of the N-type region is between about 1e14 dopants/cm³ and about 1e16 dopants/cm³.

20. The method of claim 19, wherein a doping concentration of the P-type region is greater than about 8 times the doping concentration of the N-type region.
